(19) United States
(12) Patent Application Publication
(10) Pub. No.: US 2022/0359853 A1
(43) Pub. Date: Nov. 10, 2022

(54) APPARATUS FOR MANUFACTURING DISPLAY DEVICE

(71) Applicants: Samsung Display Co., Ltd., Yongin-si (KR); Postech Research And Business Development Foundation, Pohang-si (KR)

(72) Inventors: Sungsoon Im, Yongin-si (KR); Jongkyu Kim, Pohang-si (KR); Seokho Moon, Pohang-si (KR); Jeonghyeon Park, Pohang-si (KR); Heemin Park, Yongin-si (KR); Seungyong Song, Yongin-si (KR); Duckjung Lee, Yongin-si (KR); Heonwoong Hwang, Pohang-si (KR)

(73) Assignees: Samsung Display Co., Ltd., Yongin-si (KR); Postech Research And Business Development Foundation, Pohang-si (KR)

(21) Appl. No.: 17/737,893

(22) Filed: May 5, 2022

(30) Foreign Application Priority Data
May 6, 2021 (KR) 10-2021-0058766

(51) Int. Cl. H01L 51/56; H01L 51/00; C23C 14/12; C23C 14/04

(52) U.S. Cl. CPC H01L 51/56; H01L 51/0011; C23C 14/12; C23C 14/048; H01L 27/3246

(57) ABSTRACT

An apparatus for manufacturing a display device includes: a support to mount a display substrate having a pixel area; a multi-layered film disposed above the display substrate and including a light-transmissive base layer and a source layer disposed on the base layer facing the pixel area and including an organic material; and a laser device spaced apart from the multi-layered film to radiate a laser beam toward the multi-layered film. The source layer is capable of absorbing the laser beam.

### CROSS-REFERENCE TO RELATED APPLICATION

This application claims priority from and the benefit of Korean Patent Application No. 10-2021-0058766, filed on May 6, 2021, which is hereby incorporated by reference for all purposes as if fully set forth herein.

### BACKGROUND

### Field

Embodiments of the invention relate generally to apparatus for manufacturing a display device, and more specifically, to apparatus for manufacturing a display device to form one or more layers on a display substrate.

### Discussion of the Background

Display devices provide visual information such as an image or video to a user. With the development of various electronic devices such as computers and wide-screen televisions (TVs), various types of display devices applicable thereto have been developed. Recently, mobile electronic devices have been widely used, and as mobile electronic devices, tablet personal computers (PCs) have recently been widely used in addition to small electronic devices such as mobile phones.

Among display devices, organic light-emitting display devices have been widely used because of their advantages such as a wide viewing angle, a high contrast ratio, and a high response speed. In general, an organic light-emitting display device includes thin-film transistors and organic light-emitting diodes on a substrate, and the organic light-emitting diodes may include an organic material layer such as an emission layer capable of emitting light by itself.

To manufacture the organic light-emitting display device, the organic material layer such as the emission layer has to be patterned for each pixel area, and a mask deposition method using a fine metal mask (FMM) may be used to form the patterned emission layer in each pixel area.

The above information disclosed in this Background section is only for understanding of the background of the inventive concepts, and, therefore, it may contain information that does not constitute prior art.

### SUMMARY

Applicant realized that the mask deposition method has drawbacks in that the level of difficulty of manufacturing the mask is high and the resulting cost of the mask also is high, thereby increasing the unit cost of a display device. In addition, as the size of the mask increases according to a recent trend to increase the size of the display device, sagging of the mask increases, which may cause difficulty in precise deposition and reduction in manufacturing yield of the display device.

Apparatus for manufacturing a display device constructed according to principles and illustrative embodiments of the invention are capable of manufacturing the display device cost-effectively with relatively high manufacturing yield and reliability. For example, the apparatus may include a multi-layered film disposed above a display substrate, and may form a patterned organic material layer on the display substrate by radiating a laser beam toward the multi-layered film to transfer organic material of the multi-layered film to the display substrate. Accordingly, the apparatus for manufacturing the display device does not require a deposition mask such as an FMM to form the patterned organic material layer.

Additional features of the inventive concepts will be set forth in the description which follows, and in part will be apparent from the description, or may be learned by practice of the inventive concepts.

According to one aspect of the invention, an apparatus for manufacturing a display device includes: a support to mount a display substrate having a pixel area; a multi-layered film disposed above the display substrate and including a light-transmissive base layer and a source layer disposed on the base layer facing the pixel area and including an organic material; and a laser device spaced apart from the multi-layered film to radiate a laser beam toward the multi-layered film. The source layer is capable of absorbing the laser beam.

The laser beam may have a first wavelength band of about 300 nm to about 700 nm or a second wavelength band of about 800 nm to about 20,000 nm.

The multi-layered film may include a donor film, and the source layer may include a transfer layer having a pattern overlapping the pixel area of the display substrate.

The laser beam may have a first width in one direction and the pixel area may have a second width in the same direction, with the first width being substantially equal to or less than the second width.

The base layer may include glass or aluminum oxide (Al2O3).

The base layer may include at least one of silicon (Si), gallium arsenide (GaAs), zinc telluride (ZnTe), and zinc selenide (ZnSe).

The multi-layered film may further include a partition wall layer disposed between the base layer and the source layer and defining an opening overlapping the pixel area of the display substrate.

The partition wall layer may have a lower thermal conductivity and a smaller thermal expansion coefficient than that of the source layer.

The opening of the partition wall layer may have a first width in one direction and the pixel area may have a second width in the same direction, with the first width being substantially equal to or greater than the second width.

The partition wall layer may be thicker than the source layer.

The partition wall layer may include at least one of silicon oxide (SiO2), silicon nitride (SiNx), and aluminum oxide (Al2O3).

The multi-layered film may further include a light-to-heat conversion layer disposed between the base layer and the source layer and configured to absorb the laser beam.

The light-to-heat conversion layer may include at least one of molybdenum (Mo), titanium (Ti), chromium (Cr), tungsten (W), tin (Sn), oxides thereof, and sulfides thereof.

The multi-layered film may further include a partition wall layer disposed between the light-to-heat conversion layer and the source layer, the partition wall layer defining an opening overlapping the pixel area of the display substrate.

The apparatus may further include one or more first moveable portions supporting the laser device for movement in one or more directions intersecting an emitting direction of the laser beam.

The apparatus may further include a second moveable portion supporting the display substrate for movement relative to the multi-layered film.

The laser device may include a laser beam radiation unit including: a light source to generate the laser beam; and an optical system arranged in an emitting path of the laser beam.

The laser device may include a vertical-cavity surface-emitting laser (VCSEL).

The source layer may include the same material as an emission layer of the display device to emit visible rays.

The source layer may include the same material as at least one of a hole injection layer, a hole transport layer, an electron transport layer, and an electron injection layer of the display device.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic perspective view of an embodiment of a display device.

FIG. 2 is an equivalent circuit diagram of a representative one of the pixels of FIG.

FIG. 3 is a schematic cross-sectional view taken along line of FIG. 1.

FIG. 4 is a schematic perspective view of an embodiment of apparatus for manufacturing a display device constructed according to the principles of the invention.

FIG. 5 is a schematic cross-sectional view of an embodiment of a donor film and a display substrate at one of stages of manufacturing the display device using the laser beam radiation unit of FIG. 4.

FIGS. 6A to 6D are schematic cross-sectional views of an embodiment of a donor film and display substrates at various illustrative stages of manufacturing the display devices.

FIGS. 7A and 7B are schematic cross-sectional views of another embodiment of a donor film and a display substrate at various illustrative stages of manufacturing the display device.

FIG. 8 is a schematic cross-sectional view of still another embodiment of a donor film and a display substrate at one illustrative stage of manufacturing the display device.

FIG. 9 is a schematic cross-sectional view of yet another embodiment of a donor film and a display substrate at one illustrative stage of manufacturing the display device.

FIG. 10 is a schematic cross-sectional view of still yet another embodiment of a donor film and a display substrate at one illustrative stage of manufacturing the display device.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z—axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

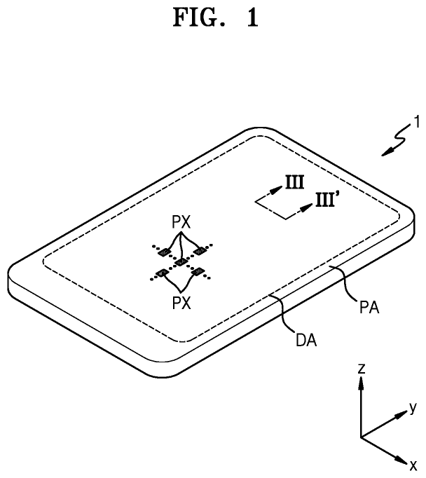

FIG. 1 is a schematic perspective view of an embodiment of a display device.

Referring to FIG. 1, a display device 1 may include a display area DA and a peripheral area PA outside the display area DA. The display device 1 may provide an image through an array of a plurality of pixels PX in the display area DA. A pixel PX may include a light-emitting element and a pixel circuit for driving the light-emitting element. The pixel PX may emit light through the light-emitting element, and an image may be provided by the light emitted from the pixel PX. Not only light-emitting elements and pixel circuits but also various signal lines and power lines electrically connected to the pixel circuits may be arranged in the display area DA.

The peripheral area PA is an area that provides no image, and may entirely or partially surround the display area DA. Various wirings, driving circuits, etc. for providing electrical signals or power to the display area DA may be arranged in the peripheral area PA.

The display device 1 may have a substantially rectangular shape in a direction vertical to one surface thereof. For example, as shown in FIG. 1, the display device 1 may entirely have a rectangular planar shape, for example, having a short side extending in a direction x and a long side extending in a direction y. A corner at which the short side in the direction x and the long side in the direction y meet each other may have a right-angled shape, or may have a round shape having a certain curvature as shown in FIG. 1. However, the planar shape of the display device 1 is not limited to a rectangular shape, and may have various shapes, such as a polygonal shape such as a triangle, a circular shape, an oval shape, or an atypical shape.

FIG. 1 shows the display device 1 having a flat display surface, but the embodiments are not limited thereto. In an embodiment, the display device 1 may include a stereoscopic display surface or a curved display surface. In the case where the display device 1 includes a stereoscopic display surface, the display device 1 may include a plurality of display areas facing different directions, and for example, may include a polygonal columnar display surface. In the case where the display device 1 includes a curved display surface, the display device 1 may be implemented in various forms such as a flexible, foldable, or rollable display device.

The display device 1 is shown as being used in a smart phone as a convenient example, but embodiments are not limited thereto. The display device 1 may be used as the display screens of not only portable electronic devices, such as a mobile phone, a smart phone, a tablet personal computer (PC), a mobile communication terminal, an electronic notebook, an e-book, a portable multimedia player (PMP), a navigation system, and an ultra-mobile PC (UMPC), but also various other products, such as a television, a laptop, a monitor, a billboard, and the Internet of things (IoT). In other examples, the display device 1 may be used in wearable devices, such as a smart watch, a watch phone, a glasses-type display, and a head-mounted display (HMD). In still other examples, the display device 1 may be used as a car's instrument cluster, a center information display (CID) arranged on a car's center fascia or dashboard, a room mirror display replacing a car's side mirror, or a display screen arranged on the back of a front seat as entertainment for a car's rear seat.

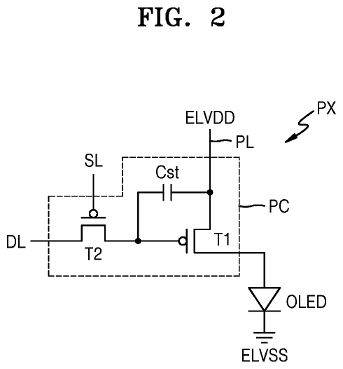

FIG. 2 is an equivalent circuit diagram of a representative one of the pixels of FIG. 1.

Referring to FIG. 2, the pixel PX may include a light-emitting element such as an organic light-emitting diode OLED, and the pixel circuit PC for driving the organic light-emitting diode OLED. The pixel circuit PC may include a plurality of thin-film transistors and a storage capacitor and may be electrically connected to the organic light-emitting diode OLED. In an embodiment, the pixel circuit PC may include a driving thin-film transistor T1, a switching thin-film transistor T2, and a storage capacitor Cst.

The switching thin-film transistor T2 is connected to a scan line SL and a data line DL, and may be configured to transmit a data signal or a data voltage input from the data line DL to the driving thin-film transistor T1, based on a scan signal or a switching voltage input from the scan line SL. The storage capacitor Cst is connected to the switching thin-film transistor T2 and a driving voltage line PL, and may store a voltage corresponding to a difference between a voltage received from the switching thin-film transistor T2 and a first power voltage ELVDD supplied to the driving voltage line PL.

The driving thin-film transistor T1 is connected to the driving voltage line PL and the storage capacitor Cst, and may be configured to control a driving current flowing through the organic light-emitting diode OLED from the driving voltage line PL, in response to a voltage value stored in the storage capacitor Cst. An opposite electrode (e.g., a cathode) of the organic light-emitting diode OLED may receive a second power voltage ELVSS. The organic light-emitting diode OLED may emit light having certain brightness due to a driving current.

A case in which the pixel circuit PC includes two thin-film transistors and one storage capacitor has been described, but the embodiments are not limited thereto. For example, the pixel circuit PC may include three or more thin-film transistors and/or two or more storage capacitors. In an embodiment, the pixel circuit PC may include seven thin-film transistors and one storage capacitor. The number of thin-film transistors and storage capacitors may be variously modified according to the design of the pixel circuit PC. However, a case in which the pixel circuit PC includes two thin-film transistors and one storage capacitor is described herein for illustrative purposes.

The display device 1 may include an organic light-emitting diode OLED as a light-emitting element, but embodiments are not limited thereto.

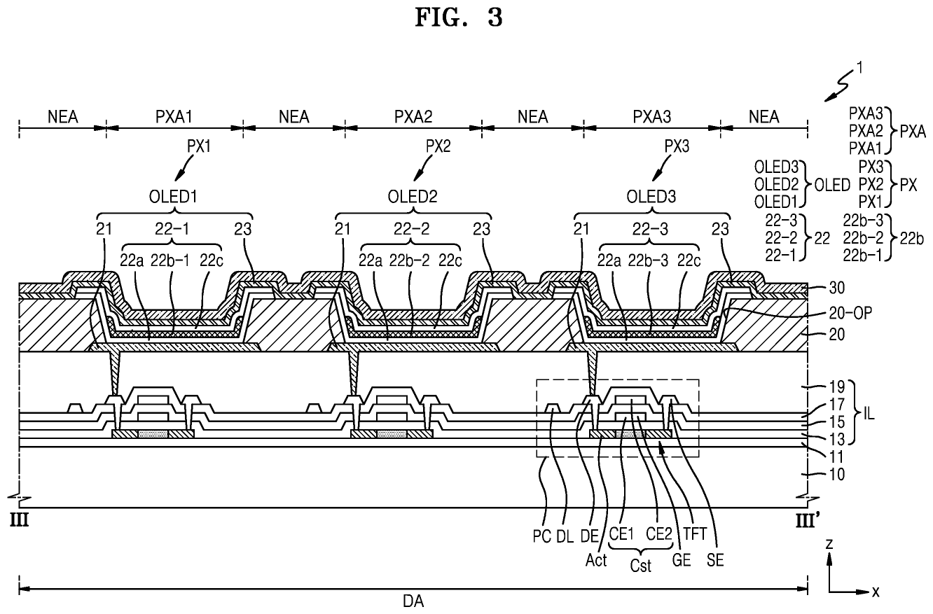

FIG. 3 is a schematic cross-sectional view taken along line of FIG. 1.

Referring to FIG. 3, the display area DA of the display device 1 may include pixel areas PXA and non-emission areas NEA. The pixel area PXA may be defined as an area where light is emitted by the pixel PX corresponding thereto, and the non-emission area NEA may be defined as an area where no light is emitted. One pixel PX may be arranged in each pixel area PXA. For example, the organic light-emitting diode OLED may be arranged in the pixel area PXA. The pixel circuit PC electrically connected to the organic light-emitting diode OLED may also be arranged in the pixel area PXA corresponding thereto, but embodiments are not limited thereto. At least a portion of the pixel circuit PC may be arranged in the non-emission area NEA. Hereinafter, a stacked structure of the organic light-emitting diode OLED and the pixel circuit PC will be described.

The display device 1 may include a substrate 10. The substrate 10 may include a glass material or polymer resin. In an embodiment, the substrate 10 may include a plurality of sub-layers. The plurality of sub-layers may have a structure in which an organic layer and an inorganic layer are alternately stacked. When the substrate 10 includes polymer resin, the substrate 10 may include polyethersulfone, polyacrylate, polyetherimide, polyethylene naphthalate, polyethylene terephthalate, polyphenylene sulfide, polyarylate, polyimide, polycarbonate, or cellulose acetate propionate.

A buffer layer 11 may be arranged on the substrate 10. The buffer layer 11 may prevent impurities from penetrating into a semiconductor layer Act of a thin-film transistor TFT. In an embodiment, the buffer layer 11 may include an inorganic insulating material such as silicon nitride, silicon oxynitride, and silicon oxide, and may have a single-layer or multi-layer structure including the above-described inorganic insulating material.

A plurality of pixel circuits PC may be arranged on the buffer layer 11. As an example, structures of the plurality of pixel circuits PC respectively included in the plurality of pixels PX are the same as each other, and thus, one pixel circuit PC will be mainly described.

The pixel circuit PC may include a plurality of thin-film transistors and the storage capacitor Cst. One thin-film transistor TFT of the plurality of thin-film transistors is shown in FIG. 3, and as an example, the thin-film transistor TFT may be the driving thin-film transistor T1 of FIG. 2. The switching thin-film transistor T2 of FIG. 2 included in the pixel circuit PC may be electrically connected to the data line DL.

The thin-film transistor TFT may include the semiconductor layer Act, a gate electrode GE, a source electrode SE, and a drain electrode DE.

As an example, the semiconductor layer Act may include polysilicon. As another example, the semiconductor layer Act may include amorphous silicon, may include an oxide semiconductor, or may include an organic semiconductor.

The gate electrode GE may include a low-resistance metal material. The gate electrode GE may include a conductive material including molybdenum (Mo), aluminum (Al), copper (Cu), titanium (Ti), etc. and may have a multi-layer or single-layer structure including the above-described material.

A gate insulating layer 13 between the semiconductor layer Act and the gate electrode GE may include an inorganic insulating material such as silicon oxide, silicon nitride, silicon oxynitride, aluminum oxide, titanium oxide, tantalum oxide, and hafnium oxide. The gate insulating layer 13 may have a single-layer or multi-layer structure including the above-described material.

FIG. 3 shows the thin-film transistor TFT of a top gate type in which the gate electrode GE is arranged above the semiconductor layer Act with the gate insulating layer 13 therebetween, but embodiments are not limited thereto. For example, the thin-film transistor TFT may have a bottom gate type design.

The source electrode SE and the drain electrode DE may be on the same layer as the data line DL and may include the same material as the data line DL. The source electrode SE, the drain electrode DE, and the data line DL may each include a highly conductive material. The source electrode SE, the drain electrode DE, and the data line DL may each include a conductive material including molybdenum (Mo), aluminum (Al), copper (Cu), titanium (Ti), etc. and may each have a multi-layer or single-layer structure including the above-described material. In an embodiment, the source electrode SE, the drain electrode DE, and the data line DL may each have a multi-layer structure of Ti/Al/Ti.

The storage capacitor Cst may include a lower electrode CE1 and an upper electrode CE2 overlapping each other with a first interlayer insulating layer 15 therebetween. The storage capacitor Cst may overlap the thin-film transistor TFT. For example, the gate electrode GE of the thin-film transistor TFT may be the lower electrode CE1 of the storage capacitor Cst as shown in FIG. 3. In another embodiment, the storage capacitor Cst may not overlap the thin-film transistor TFT. The storage capacitor Cst may be covered by a second interlayer insulating layer 17. The upper electrode CE2 of the storage capacitor Cst may include a conductive material including molybdenum (Mo), aluminum (Al), copper (Cu), titanium (Ti), etc. and may have a multi-layer or single-layer structure including the above-described material.

The first interlayer insulating layer 15 and the second interlayer insulating layer 17 may each include an inorganic insulating material such as silicon oxide, silicon nitride, silicon oxynitride, aluminum oxide, titanium oxide, tantalum oxide, and hafnium oxide. The first interlayer insulating layer 15 and the second interlayer insulating layer 17 may each have a single-layer or multi-layer structure including the above-described material.

The pixel circuit PC including the thin-film transistor TFT and the storage capacitor Cst may be covered by an organic insulating layer 19. An upper surface of the organic insulating layer 19 has a substantially flat surface and may provide a flat surface for the organic light-emitting diode OLED arranged thereon.

Another inorganic insulating layer may be further arranged under the organic insulating layer 19, and another organic insulating layer may be arranged on the organic insulating layer 19. Thus, pixel circuit PC may be formed.

The organic insulating layer 19 may include an organic insulating material such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof. In an embodiment, the organic insulating layer 19 may include polyimide. The gate insulating layer 13, the first interlayer insulating layer 15, the second interlayer insulating layer 17, and the organic insulating layer 19 described above may be collectively referred to as one or more insulating layers IL.

A plurality of organic light-emitting diodes OLED may be arranged on the organic insulating layer 19. For example, a first organic light-emitting diode OLED1, a second organic light-emitting diode OLED2, and a third organic light-emitting diode OLED3 adjacent to one another may be arranged on the organic insulating layer 19. The first to third organic light-emitting diodes OLED1 to OLED3 may respectively emit light of different colors, and for example, may emit red light, green light, and blue light, respectively.

Each organic light-emitting diode OLED may include a stacked structure of a pixel electrode 21, an intermediate layer 22, and an opposite electrode 23. In an embodiment, the first organic light-emitting diode OLED1 may include the pixel electrode 21, a first intermediate layer 22-1 including a first emission layer 22b-1, and the opposite electrode 23. The second organic light-emitting diode OLED2 may include the pixel electrode 21, a second intermediate layer 22-2 including a second emission layer 22b-2, and the opposite electrode 23. The third organic light-emitting diode OLED3 may include the pixel electrode 21, a third intermediate layer 22-3 including a third emission layer 22b-3, and the opposite electrode 23.

Each organic light-emitting diode OLED may be electrically connected to the pixel circuit PC corresponding thereto. For example, the pixel electrode 21 of each organic light-emitting diode OLED may be electrically connected to the thin-film transistor TFT of the pixel circuit PC corresponding thereto through a contact hole formed in the organic insulating layer 19.

The pixel electrode 21 of each organic light-emitting diode OLED may be arranged on the organic insulating layer 19. Each pixel electrode 21 may be formed in an isolated shape (that is, an island shape) in a plan view. In this regard, ‘in a plan view’ may refer to ‘in a direction vertical to one surface of the substrate 10’.

The pixel electrode 21 may include conductive oxide such as indium tin oxide (ITO), indium zinc oxide (IZO), zinc oxide (ZnO), indium oxide (In2O3), indium gallium oxide (IGO), or aluminum zinc oxide (AZO). In another embodiment, the pixel electrode 21 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 21 may further include a film on/under the above-described reflective film and including ITO, IZO, ZnO, or In2O3.

A pixel-defining layer 20 may be arranged on the pixel electrode 21. The pixel-defining layer 20 may include an opening 20-OP exposing an upper surface of the pixel electrode 21 but may cover edges of the pixel electrode 21. The pixel-defining layer 20 may include an organic insulating material. Alternatively, the pixel-defining layer 20 may include an inorganic insulating material such as silicon nitride, silicon oxynitride, or silicon oxide. Alternatively, the pixel-defining layer 20 may include an organic insulating material and an inorganic insulating material.

An emission layer 22b may be arranged above each pixel electrode 21. For example, one of the first emission layer 22b-1, the second emission layer 22b-2, and the third emission layer 22b-3 may be arranged above each pixel electrode 21. The emission layer 22b may be in the opening 20-OP of the pixel-defining layer 20.

The emission layer 22b may include a polymer or low-molecular weight organic material emitting light of a certain color. The emission layer 22b may emit light in a certain wavelength band, and for example, may emit light in a wavelength band of visible rays. In an embodiment, the first to third emission layers 22b-1 to 22b-3 may emit light in different wavelength bands from one another. For example, the first to third emission layers 22b-1 to 22b-3 may emit red light, green light, and blue light, respectively, and in this regard, red light may be light in a wavelength band of about 580 nm to about 780 nm, green light may be light in a wavelength band of about 495 nm to about 580 nm, and blue light may be light in a wavelength band of about 400 nm to about 495 nm.

In an embodiment, a lower common layer 22a may be arranged under the emission layer 22b. The lower common layer 22a may be disposed between the pixel electrode 21 and the emission layer 22b. The lower common layer 22a may overlap each pixel electrode 21. As an example, a plurality of lower common layers 22a may overlap a plurality of pixel electrodes 21, respectively, as shown in FIG. 3. In this case, each of the plurality of lower common layers 22a may have an isolated shape (or an island shape) in a plan view. As another example, a lower common layer may be integrally formed to overlap the plurality of pixel electrodes 21. For convenience of description, a case in which the display device 1 includes the plurality of lower common layers 22a in isolated shapes is described herein.

The lower common layer 22a may have a single-layer or multi-layer structure. For example, in a case where the lower common layer 22a includes a polymer material, the lower common layer 22a is a hole transport layer (HTL) having a single-layer structure, and may include poly(3,4-ethylenedioxythiophene) (PEDOT) or polyaniline (PANI). In a case where the lower common layer 22a includes a low-molecular weight material, the lower common layer 22a may include a hole injection layer (HIL) and an HTL.

In addition, an upper common layer 22c may be arranged on the emission layer 22b. The upper common layer 22c may be disposed between the emission layer 22b and the opposite electrode 23 described below. The upper common layer 22c may overlap the pixel electrode 21. As an example, a plurality of upper common layers 22c may overlap the plurality of pixel electrodes 21, respectively, as shown in FIG. 3. In this case, each of the plurality of upper common layers 22c may have an isolated shape (i.e., an island shape) in a plan view. As another example, an upper common layer may be integrally formed to overlap the plurality of pixel electrodes 21. For convenience of description, a case in which the display device 1 includes the plurality of upper common layers 22c in isolated shapes is described herein.

The upper common layer 22c may not be necessarily provided. For example, in case where the lower common layer 22a and the first emission layer 22b-1 each include a polymer material, the upper common layer 22c may be provided for each pixel PX. The upper common layer 22c may have a single-layer or multi-layer structure. The upper common layer 22c may include an electron transport layer (ETL) and/or an electron injection layer (EIL).

The intermediate layer 22 may be formed by the stacked structure of the lower common layer 22a, the emission layer 22b, and the upper common layer 22c described above. For example, the lower common layer 22a, the first emission layer 22b-1, and the upper common layer 22c may form a first intermediate layer 22-1, and the lower common layer 22a, the second emission layer 22b-2, and the upper common layer 22c may form a second intermediate layer 22-2, and the lower common layer 22a, the third emission layer 22b-3, and the upper common layer 22c may form a third intermediate layer 22-3.

The opposite electrode 23 may be arranged on the first to third intermediate layers 22-1 to 22-3. That is, the opposite electrode 23 may be arranged above the first to third emission layers 22b-1 to 22b-3. The opposite electrode 23 may include a conductive material having a low work function. For example, the opposite electrode 23 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 23 may further include a layer, such as ITO, IZO, ZnO, or In2O3, on a (semi)transparent layer including the above-described material.

The opposite electrode 23 may be integrally formed over the plurality of pixel electrodes 21. For example, the opposite electrode 23 may overlap all of the first to third pixel electrodes 210-1 to 210-3. The opposite electrode 23 may be formed not only in the display area DA but also in the peripheral area PA of FIG. 1.

In some embodiments, a capping layer 30 may be on the opposite electrode 23. For example, the capping layer 30 may include a material selected from among an organic material, an inorganic material, and a mixture thereof in a single-layer or multi-layer structure. As an optional embodiment, a lithium fluoride (LiF) layer may be on the capping layer 30.

The display device 1 may include a thin film encapsulation layer arranged on the capping layer 30. The thin film encapsulation layer may directly contact the capping layer 30. In this regard, the thin film encapsulation layer may prevent penetration of external moisture and oxygen by partially covering the display area DA and the peripheral area PA (refer to FIG. 1). The thin film encapsulation layer may include at least one organic encapsulation layer and at least one inorganic encapsulation layer. For example, the thin film encapsulation layer may include a first inorganic encapsulation layer, an organic encapsulation layer, and a second inorganic encapsulation layer sequentially stacked on the capping layer 30.

In addition, a touchscreen layer, an optical functional layer such as a polarizer, and a cover window may be arranged on the thin film encapsulation layer.

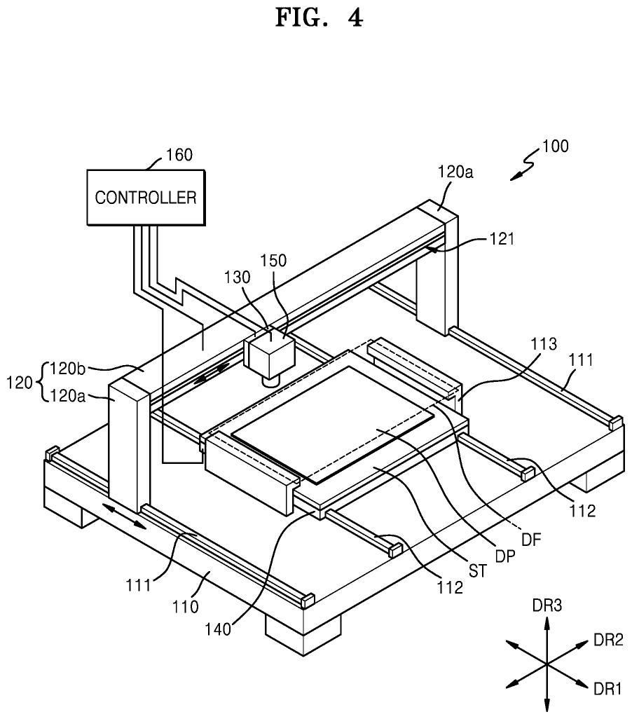

FIG. 4 is a schematic perspective view of an embodiment of apparatus for manufacturing a display device constructed according to the principles of the invention.

Referring to FIG. 4, apparatus 100 for manufacturing a display device such as the display device 1 of FIG. 1 may include a support 110, a first moving portion 120, a second moving portion 130, a third moving portion 140, a laser beam radiation unit 150, and a controller 160. In addition, the apparatus 100 for manufacturing a display device may include another support that may be in the form of a stage ST arranged above the support 110 to mount a display substrate DP, and a multi-layered film that may be in the form of a donor film DF disposed above the display substrate DP. The display substrate DP may a part of the display device 1 at one of stages of manufacturing the display device 1.

The support 110 may be disposed in a plane defined by a first direction DR1 and a second direction DR2 intersecting the first direction DR1. The first moving portion 120, the second moving portion 130, the third moving portion 140, and the laser beam radiation unit 150 may be arranged over the support 110.

The stage ST may be disposed in a plane defined by the first direction DR1 and the second direction DR2. The stage ST may constitute and/or provide an operation area at some of the processes of manufacturing the display device 1. The display substrate DP including the pixel area PXA of FIG. 3 may be mounted on the stage ST. In addition, the stage ST may include an alignment mark for arranging the display substrate DP on the stage ST. In this regard, the display substrate DP is a portion of the display device 1 being manufactured, and may be a target onto which a transfer layer of the donor film DF is transferred.

In an embodiment, a first guide portion 111 may be provided on the support 110, and the first guide portion 111 may extend, for example, in the first direction DR1. As an example, a plurality of first guide portions 111 may be provided on the support 110 and spaced apart from each other in the second direction DR2 as shown in FIG. 4. For example, the plurality of first guide portions 111 may be two and may be spaced apart from each other on two opposite sides of the stage ST. An extension length of each of the plurality of first guide portions 111 in the first direction DR1 may be at least greater than a length of an edge (or a side) of the display substrate DP in the first direction DR1. The first guide portion 111 may guide the first moving portion 120 to allow the first moving portion 120 to linearly move in an extension direction of the first guide portion 111. The first guide portion 111 may include, for example, a linear motion rail.

The first moving portion 120 may linearly reciprocate in the first direction DR1. In an embodiment, the first moving portion 120 may include pillar members 120a and a horizontal member 120b. The pillar members 120a of the first moving portion 120 may extend in a third direction DR3 intersecting each of the first direction DR1 and the second direction DR2. The pillar members 120a may be, for example, two, and may be arranged on two sides of the stage ST. The pillar members 120a may move in extension directions of the plurality of first guide portions 111, respectively, that is, in the first direction DR1. In an embodiment, the pillar members 120a may linearly move manually, or may include a motor cylinder and thus may linearly move automatically. For example, the pillar members 120a may include a linear motion block moving along a linear motion rail and thus may linearly move automatically.

The horizontal member 120b of the first moving portion 120 may extend between the pillar members 120a along the second direction DR2. Both ends of the horizontal member 120b may be connected to upper portions of the pillar members 120a, respectively. Embodiments are not limited to the structure and shape of the pillar members 120a and the horizontal member 120b shown in FIG. 4. Any structure and shape that allows the first moving portion 120 to linearly reciprocate in the first direction DR1 may be adopted without limitation.

The second moving portion 130 may linearly move in the second direction DR2. In an embodiment, the second moving portion 130 may be movably connected to one side surface of the horizontal member 120b of the first moving portion 120. As an example, the horizontal member 120b of the first moving portion 120 may include a first groove 121 extending in an extension direction of the horizontal member 120b, that is, the second direction DR2. The second moving portion 130 may be arranged on a side surface of the horizontal member 120b including the first groove 121. The first groove 121 may guide the second moving portion 130 to allow the second moving portion 130 to linearly reciprocate in an extension direction of the first groove 121. The second moving portion 130 may linearly reciprocate in the second direction DR2 along the first groove 121. In an embodiment, the second moving portion 130 may include a linear motor.

A laser device that may be in the form of the laser beam radiation unit 150, may radiate a laser beam in one direction. For example, the laser beam emitted from the laser beam radiation unit 150 may travel in the third direction DR3. The laser beam radiation unit 150 may radiate the laser beam onto the donor film DF overlapping the display substrate DP on the stage ST.

The laser beam radiation unit 150 may be arranged on one side of the second moving portion 130. The laser beam radiation unit 150 may move together as the first moving portion 120 and the second moving portion 130 move. The first moving portion 120 and the second moving portion 130 may move the laser beam radiation unit 150 in directions intersecting a traveling direction (an emitting direction) of the laser beam. For example, the first moving portion 120 and the second moving portion 130 may move the laser beam radiation unit 150 in the first direction DR1 and the second direction DR2. A moving range of the laser beam radiation unit 150 may cover an area of the support 110. Accordingly, the laser beam radiation unit 150 may radiate a laser beam to substantially an entire surface of the display substrate DP above the support 110.

The controller 160 may be electrically connected to the first moving portion 120 and the second moving portion 130 and may control a position and movement of each of the first moving portion 120 and the second moving portion 130. In addition, the controller 160 may be electrically connected to the laser beam radiation unit 150 and may control radiation time, output, etc. of the laser beam radiation unit 150.

In an embodiment, the second guide portion 112 may be provided on the support 110, and the second guide portion 112 may extend, for example, in the first direction DR1. As an example, a plurality of second guide portions 112 may be provided on the support 110 and spaced apart from each other in the second direction DR2 as shown in FIG. 4. The second guide portion 112 may guide the third moving portion 140 to allow the third moving portion 140 to linearly move in an extension direction of the second guide portion 112. The second guide portion 112 may include, for example, a linear motion rail.

The third moving portion 140 may linearly reciprocate in the first direction DR1. The third moving portion 140 may be movably connected to the second guide portion 112. The third moving portion 140 may move in an extension direction of the second guide portion 112, that is, the first direction DR1. In an embodiment, the third moving portion 140 may linearly move manually, or may include a motor cylinder and thus may linearly move automatically. For example, the third moving portion 140 may include a linear motion block moving along a linear motion rail and thus may linearly move automatically.

The third moving portion 140 is configured to allow the display substrate DP on the stage ST to move relative to the donor film DF. For example, the stage ST may be arranged on one side (or a surface) of the third moving portion 140, and as the third moving portion 140 moves, the stage ST may also move. On the other hand, the donor film DF may be fixed by a fixing portion 113 arranged on the support 110. The fixing portion 113 may include, for example, a chuck capable of fixing the donor film DF.

An embodiment in which the display substrate DP and the donor film DF are capable of being moved relative to each other by moving the stage ST has been described above as an example, but embodiments are not limited thereto. A configuration in which the display substrate DP on the stage ST is fixed and the donor film DF is moved may also be made.

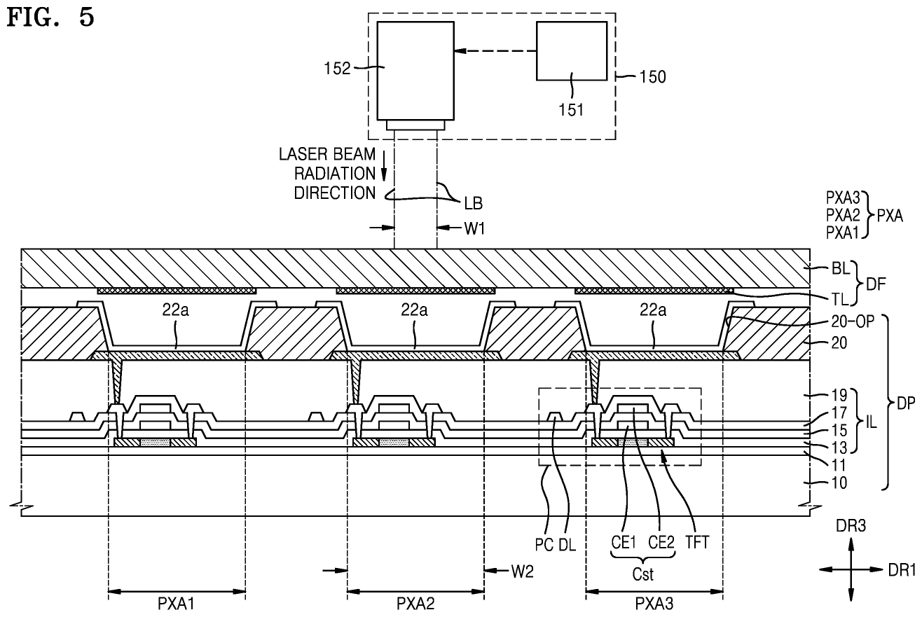

FIG. 5 is a schematic cross-sectional view of an embodiment of a donor film and a display substrate at one of stages of manufacturing the display device using the laser beam radiation unit of FIG. 4. FIG. 5 shows a portion of each of the display substrate DP, the donor film DF, and the laser beam radiation unit 150 of the apparatus 100 of FIG. 4.

Referring to FIG. 5, a display substrate DP may be a portion of the display device 1 of FIG. 3 being manufactured, and may include elements formed before formation of the organic light-emitting diode OLED of FIG. 3. For example, FIG. 5 shows the display substrate DP in an operation of forming the emission layer 22b of FIG. 3 on the display substrate DP, and in this case, the display substrate DP may include the substrate 10, the buffer layer 11, the insulating layer IL, the pixel circuit PC, the pixel electrode 21, the pixel-defining layer 20, and the lower common layer 22a. The display substrate DP may include the pixel area PXA in which the organic light-emitting diode OLED is to be arranged. Regarding each element of the display substrate DP, elements that are the same as or correspond with those of the display device 1 described above with reference to FIG. 3 are designated by the same reference numerals, and thus, duplicative descriptions thereof will be omitted to avoid redundancy.

The donor film DF may be arranged above the display substrate DP to overlap the display substrate DP. The donor film DF may include a base layer BL and a transfer layer TL arranged on the base layer BL. The base layer BL may have a sufficient supporting force to support the transfer layer TL. The base layer BL may include a relatively rigid material that prevents the base layer BL from warping or sagging. Also, the base layer BL may be light-transmissive. The base layer BL may include a material having a relatively high transmittance with respect to a laser beam LB. For example, the base layer BL may include at least one of glass, aluminum oxide (Al2O3), silicon (Si), gallium arsenide (GaAs), zinc telluride (ZnTe), and zinc selenide (ZnSe).

In an embodiment, a material of the base layer BL may be determined according to a wavelength band of the laser beam LB such that the base layer BL may transmit the laser beam LB from the laser beam radiation unit 150. When the laser beam LB has a first wavelength band of about 300 nm to about 700 nm, the base layer BL may include glass or aluminum oxide (Al2O3). When the laser beam LB has a second wavelength band of about 800 nm to about 20,000 nm, the base layer BL may include at least one of silicon (Si), gallium arsenide (GaAs), zinc telluride (ZnTe), and zinc selenide (ZnSe).

A source layer of the donor film DF, which may be in the form of the transfer layer TL, may include an organic material. An organic material of the transfer layer TL may be used to form an organic pattern layer of the organic light-emitting diode OLED on the display substrate DP. For example, the emission layer 22b, the lower common layer 22a, or the upper common layer 22c of the organic light-emitting diode OLED of FIG. 3 may be formed from the transfer layer TL. To this end, as an example, the transfer layer TL may include the same material as the emission layer 22b emitting visible rays, and as another example, the transfer layer TL may include the same material as at least one of an HIL, an HTL, an ETL, and an EIL.

The laser beam radiation unit 150 may be spaced apart from the donor film DF from above the donor film DF. The laser beam radiation unit 150 may be configured to radiate the laser beam LB toward the donor film DF.

In an embodiment, the laser beam radiation unit 150 may include a light source 151 for generating the laser beam LB and an optical system 152 arranged in a travelling path of the laser beam LB. The light source 151 may generate the laser beam LB and may use a solid-state laser such as a ruby laser or a gas laser such as a helium-neon laser. The optical system 152 may receive the generated laser beam LB from the light source 151 and adjust radiation conditions of the laser beam LB. For example, a shape and intensity of the laser beam LB, a size of a spot, a radiation angle, and the number of times of radiation may be finely adjusted. As an example, the optical system 152 may include a homogenizer for homogenizing a shape of the laser beam LB to shape the laser beam LB into a desired shape, and may include a mirror for shifting an angle of the laser beam LB. In addition, the optical system 152 may include a combination of various lens groups, such as a condensing lens or a polarizer.

In some embodiments, the laser beam radiation unit 150 may include a vertical-cavity surface-emitting laser VCSEL.

In an embodiment, the laser beam LB may have a wavelength band capable of being absorbed by the transfer layer TL of the donor film DF. For example, the laser beam LB may have a first wavelength band of about 300 nm to about 700 nm or a second wavelength band of about 800 nm to about 20,000 nm. The laser beam LB having the first or second wavelength band may be directly absorbed by the transfer layer TL without denaturing the transfer layer TL of the donor film DF, and thus, efficient transfer of the material of the transfer layer TL may be achieved.

According to an embodiment, an organic pattern layer may be formed on the display substrate DP through the apparatus 100 for manufacturing a display device. When the laser beam radiation unit 150 radiates the laser beam LB onto the donor film DF, the transfer layer TL of the donor film DF may generate heat by absorbing the laser beam LB. Accordingly, the transfer layer TL may be expanded or sublimed, and the organic material of the transfer layer TL may be transferred onto the display substrate DP adjacent to the donor film DF. Because the transfer layer TL may be transferred by directly absorbing the laser beam LB, a structure of the donor film DF may be simplified. Also, since the donor film DF adjacent to the display substrate DP is used to form the organic pattern layer on the display substrate DP and accordingly a deposition mask is not required, the manufacturing process and system for forming the organic pattern layer may be simplified. The donor film DF and/or the system including the donor film DF having a simplified structure may lead to cost reduction and may make it easy to manufacture the display device 1 having a large area.

In an embodiment, a size of a spot of the laser beam LB may be less than a size of the pixel area PXA of the display substrate DP. For example, a width W1 of the laser beam LB in the first direction DR1 may be substantially equal to or less than a width W2 of the pixel area PXA of the display substrate DP in the first direction DR1. Thus, it may be easier to form the emission layer 22b of FIG. 3, etc. in the pixel area PXA, and precise radiation may be performed to transfer the organic material of the transfer layer TL only to the pixel area PXA being targeted.

In an embodiment, the transfer layer TL of the donor film DF may include patterns corresponding respectively to the first to third pixel areas PXA1 to PXA3 of the display substrate DP. Thus, the transfer layer TL may locally absorb the laser beam LB only in an area irradiated with the laser beam LB, and heat conduction to the transfer layer TL in another area may be reduced. Accordingly, an organic material of the transfer layer TL may be transferred only in the pixel area PXA being targeted, and thus, manufacturing quality, yield, and precision may be improved.

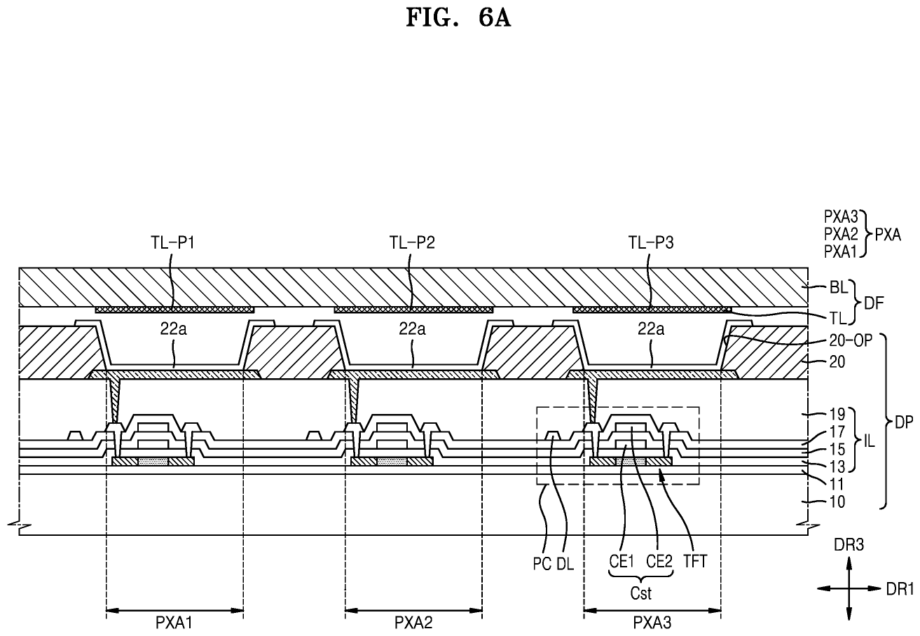

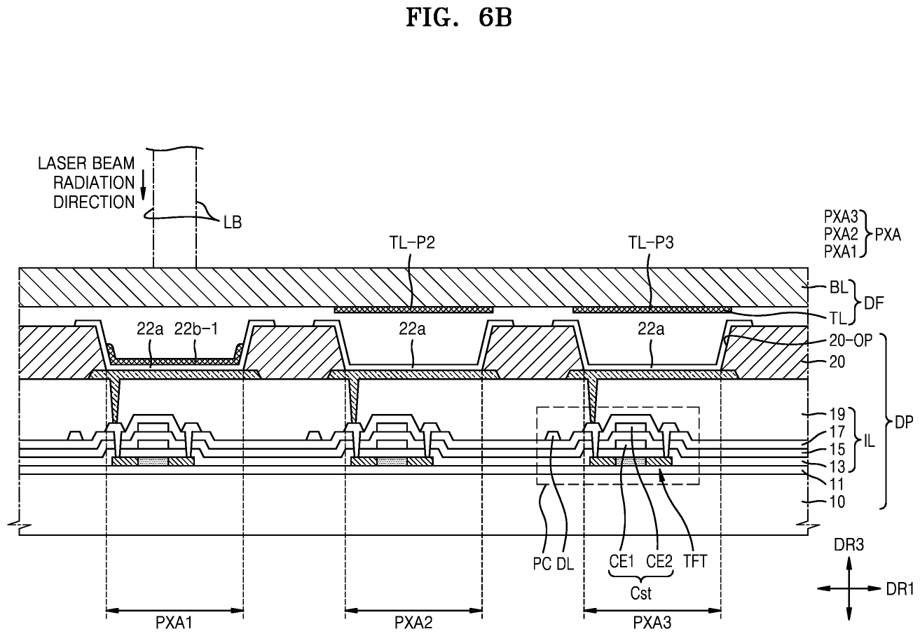

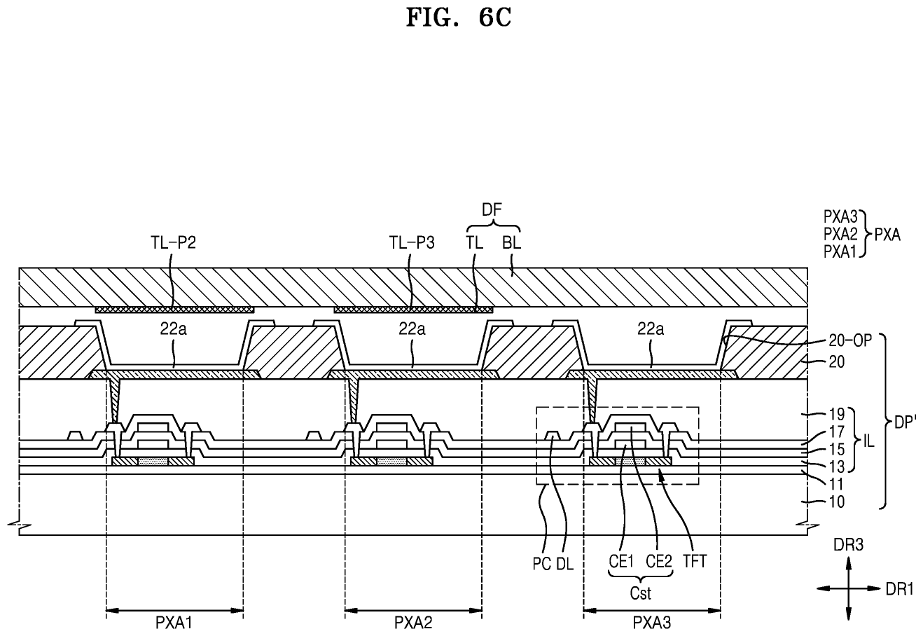

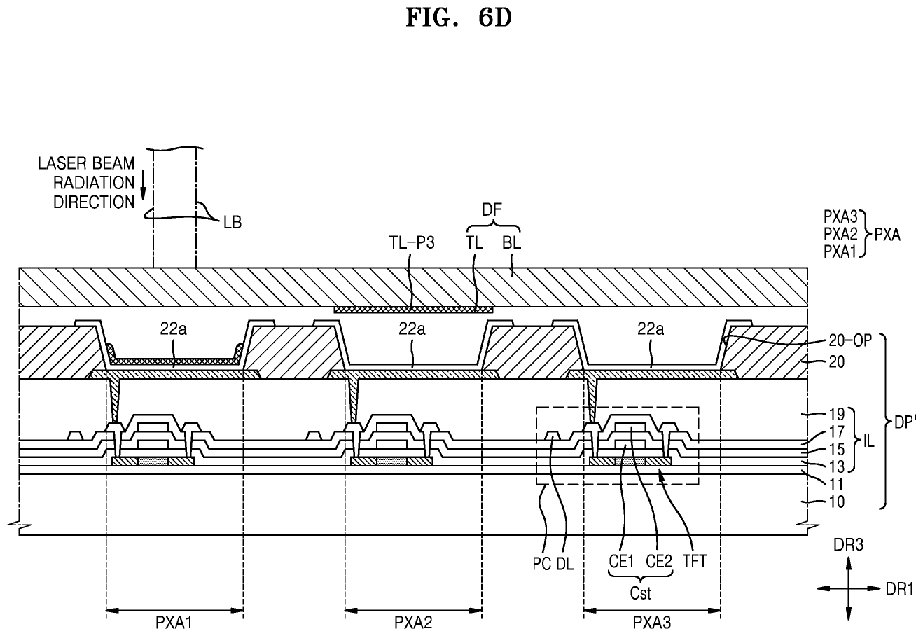

FIGS. 6A to 6D are schematic cross-sectional views of an embodiment of a donor film and display substrates at various illustrative stages of manufacturing the display devices. FIGS. 6A to 6D illustrate operations of forming the first emission layer 22b-1 of FIG. 3 on each of display substrates DP and DP′. Elements that are the same as or in correspondence with those described above with reference to FIG. 5 are designated by the same reference numerals, and thus, duplicative descriptions thereof will be omitted to avoid redundancy.

Referring to FIG. 6A, the display substrate DP and the donor film DF may be aligned with each other. The donor film DF may include the transfer layer TL having been patterned, and for example, the transfer layer TL may include a first pattern portion TL-P1, a second pattern portion TL-P2, and a third pattern portion TL-P3. Each pattern portion of the transfer layer TL may be aligned with the pixel area PXA of the display substrate DP to correspond thereto. For example, the first pattern portion TL-P1, the second pattern portion TL-P2, and the third pattern portion TL-P3 of the transfer layer TL may be aligned with a first pixel area PXA1, a second pixel area PXA2, and a third pixel area PXA3 of the display substrate DP, respectively, to correspond thereto. The third moving portion 140 of FIG. 4 described above may be used to align the display substrate DP and the donor film DF with each other.

For convenience of description, a case in which the transfer layer TL shown in FIGS. 6A to 6D includes the same material as the first emission layer 22b-1 of FIG. 3 emitting red light is described below.

Referring to FIG. 6B, the laser beam LB may be radiated toward the donor film DF. The laser beam LB may pass through the base layer BL of the donor film DF and reach the transfer layer TL. The transfer layer TL may absorb the laser beam LB. In this regard, the laser beam LB has a first wavelength band of about 300 nm to about 700 nm or a second wavelength band of about 800 nm to about 20,000 nm, and thus, the transfer layer TL absorbing the laser beam LB may not be denatured.

The transfer layer TL may generate heat by absorbing the laser beam LB, and accordingly, the transfer layer TL may be expanded or sublimed and be transferred onto the display substrate DP adjacent thereto. That is, an organic material of the transfer layer TL may be attached and/or deposited to the pixel area PXA in the display substrate DP. Thus, the emission layer 22b of FIG. 3 may be formed in the pixel area PXA.

For example, as shown in FIG. 6B, the first emission layer 22b-1 may be formed in the first pixel area PXA1 by radiating the laser beam LB to the first pattern portion TL-P1 of the transfer layer TL. The first to third pattern portions TL-P1 to TL-P3 may include a material the same as each other. In this regard, the laser beam LB is not radiated to other portions of the transfer layer TL, such as the second pattern portion TL-P2 and the third pattern portion TL-P3, and accordingly, the first emission layer 22b-1 is not formed in the second pixel area PXA2 and the third pixel area PXA3. The reason is that the second emission layer 22b-2 of FIG. 3 and the third emission layer 22b-3 of FIG. 3 have to be formed in the second pixel area PXA2 and the third pixel area PXA3, respectively.

Referring to FIG. 6C, another display substrate DP′ on which the first emission layer 22b-1 is not formed may be prepared. The display substrate DP′ and the donor film DF may be aligned with each other again. For example, the second pattern portion TL-P2 of the transfer layer TL may be aligned with the first pixel area PXA1 of the display substrate DP′ to correspond thereto. To this end, the third moving portion 140 described above may move the display substrate DP′ in a unit of the pixel area PXA.

Referring to FIG. 6D, the first emission layer 22b-1 may be formed in the first pixel area PXA1 of the display substrate DP′ by radiating the laser beam LB to the second pattern portion TL-P2 of the transfer layer TL. In this regard, the laser beam LB is not radiated to another portion of the transfer layer TL, such as the third pattern portion TL-P3, and accordingly, the first emission layer 22b-1 may not be formed in the second pixel area PXA2.

As described above, by selectively radiating the laser beam LB after aligning the display substrate DP′ and the donor film DF with each other again, the same donor film DF may be used repeatedly, and accordingly, an organic material of the transfer layer TL in the donor film DF may be used without waste.

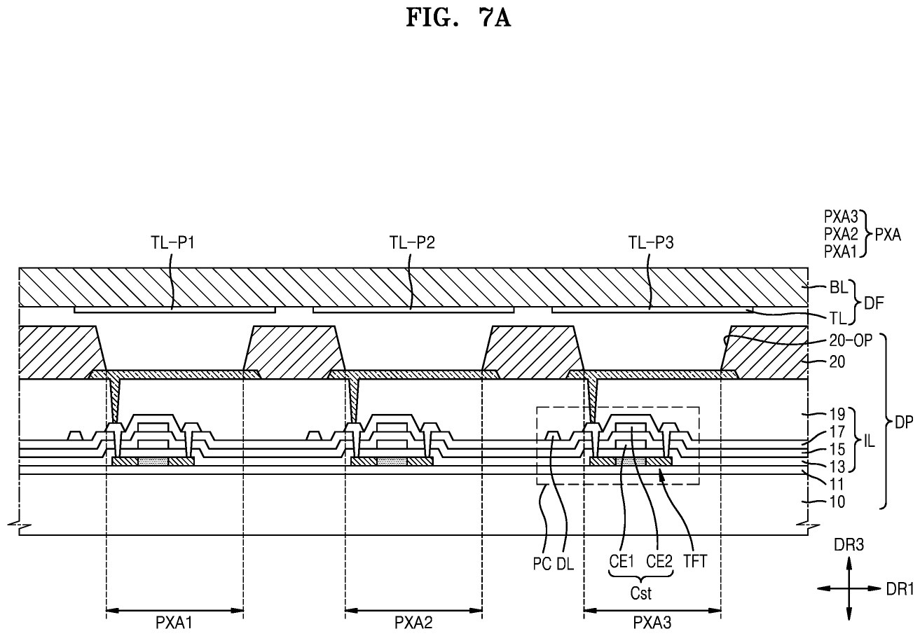

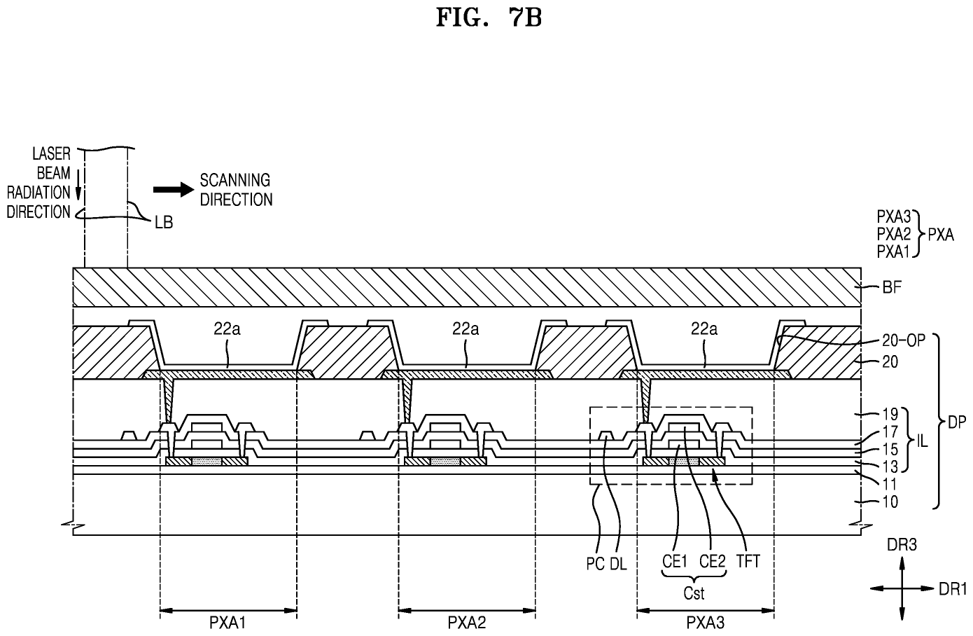

FIGS. 7A and 7B are schematic cross-sectional views of another embodiment of a donor film and a display substrate at various illustrative stages of manufacturing the display device. FIGS. 7A and 7B illustrate operations of forming the lower common layer 22a of FIG. 3 on the display substrate DP. Descriptions that have been made above with reference to FIGS. 6A and 6B will be omitted to avoid redundancy.

Referring to FIG. 7A, the display substrate DP and the donor film DF may be aligned with each other. The donor film DF may include the transfer layer TL including first to third pattern portions TL-P1 to TL-P3. In an embodiment, the first to third pattern portions TL-P1 to TL-P3 of the transfer layer TL may include the same material as the lower common layer 22a of FIG. 3 or the upper common layer 22c of FIG. 3. For example, the transfer layer TL may include the same material as at least one of an HIL, an HTL, an ETL, and an EIL. For convenience of description, a case in which, in FIGS. 7A and 7B, the transfer layer TL includes a material of an HIL and/or an HTL and is used to form the lower common layer 22a is described below.

Referring to FIG. 7B, the laser beam LB may be radiated toward the donor film DF. The laser beam LB may be radiated to an entire surface of the donor film DF. To this end, the laser beam LB may scan the donor film DF, for example, in the first direction DR1 of FIG. 4. The laser beam LB may also be scanned in the second direction DR2 of FIG. 4. The transfer layer TL may be transferred onto the display substrate DP adjacent thereto by absorbing the laser beam LB. Accordingly, the lower common layer 22a may be formed in the first to third pixel areas PXA1 to PXA3 of the display substrate DP.

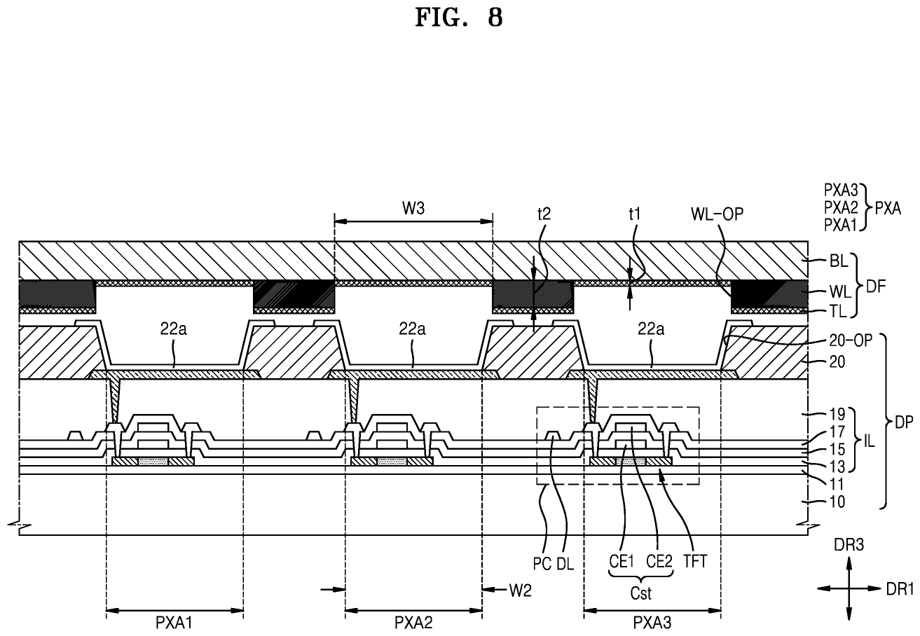

FIG. 8 is a schematic cross-sectional view of still another embodiment of a donor film and a display substrate at one illustrative stage of manufacturing the display device. Elements that are the same as or in correspondence with those described above with reference to FIG. 5 are designated by the same reference numerals, and thus, duplicative descriptions thereof will be omitted to avoid redundancy.

Referring to FIG. 8, the donor film DF may further include a partition wall layer WL between the base layer BL and the transfer layer TL. In an embodiment, the partition wall layer WL may define an opening WL-OP overlapping the pixel area PXA of the display substrate DP. The partition wall layer WL may be formed on the base layer BL first, and then, the transfer layer TL may be formed on the partition wall layer WL and a portion of the base layer BL exposed by the opening WL-OP. As an example, the transfer layer TL of the donor film DF may be formed over an entire surface of the base layer BL. Accordingly, a portion of the transfer layer TL may overlap the partition wall layer WL, and the other portion may be in the opening WL-OP of the partition wall layer WL.

According to an embodiment, the partition wall layer WL of the donor film DF may have a relatively low light transmittance, and may have a relatively high reflectance with respect to the laser beam LB. In addition, a thickness t2 of the partition wall layer WL may be greater than a thickness t1 of the transfer layer TL. Accordingly, when the laser beam LB of FIG. 5 is radiated to the donor film DF, the laser beam LB may reach the transfer layer TL in the opening WL-OP of the partition wall layer WL but may not reach the transfer layer TL overlapping the partition wall layer WL. The reason is that the laser beam LB may be blocked by the partition wall layer WL. Accordingly, only the transfer layer TL in the opening WL-OP of the partition wall layer WL overlapping the pixel area PXA may be transferred onto the display substrate DP. Thus, an organic material of the transfer layer TL may be transferred accurately. In addition, when the transfer layer TL is formed on the base layer BL of the donor film DF, a process of patterning the transfer layer TL is not required.

As an example, the thickness t2 of the partition wall layer WL may be about two to five times greater than the thickness t1 of the transfer layer TL. As the thickness t2 of the partition wall layer WL increases, the blocking effect of the laser beam LB may increase. However, when the thickness t2 of the partition wall layer WL excessively increases, it may not be easy to form the transfer layer TL in the opening WL-OP of the partition wall layer WL. Considering these points, the thickness t2 of the partition wall layer WL may be about two to five times greater than the thickness t1 of the transfer layer TL.

According to an embodiment, the partition wall layer WL of the donor film DF may have a lower thermal conductivity and a smaller thermal expansion coefficient than the transfer layer TL. As the transfer layer TL absorbs the laser beam LB, heat is generated, and the partition wall layer WL may prevent the heat from being conducted around. That is, the transfer layer TL may be transferred onto the display substrate DP locally only in an area irradiated with the laser beam LB. Accordingly, an organic material of the transfer layer TL may be transferred only in a desired area to improve manufacturing quality, yield, and precision.

In an embodiment, the partition wall layer WL may include at least one of silicon oxide (SiO₂), silicon nitride (SiNₓ), and aluminum oxide (Al₂O₃). For example, in case where the laser beam LB has a first wavelength band of about 300 nm to about 700 nm, the partition wall layer WL may include at least one of silicon oxide (SiO2) and silicon nitride (SiNₓ). In case where the laser beam LB has a second wavelength band of about 800 nm to about 20,000 nm, the partition wall layer WL may include aluminum oxide (Al₂O₃).

According to an embodiment, a width W3 of the opening WL-OP of the partition wall layer WL in the first direction DR1 may be equal to or greater than the width W2 of the pixel area PXA of the display substrate DP in the first direction DR1. Thus, an organic material of the transfer layer TL may be sufficiently transferred over the pixel area PXA to form an organic patter layer such as the emission layer 22b of FIG. 3 in the pixel area PXA.

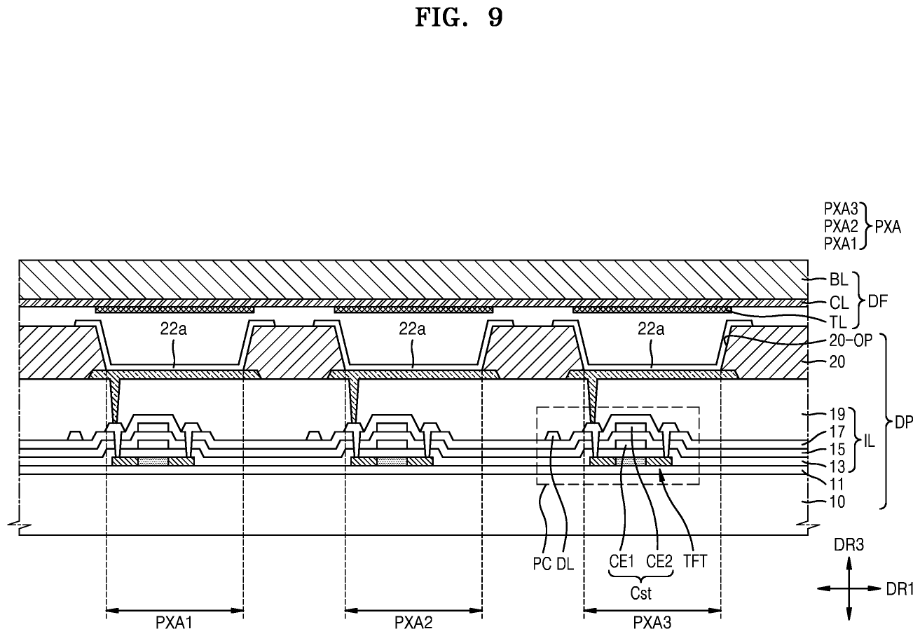

FIG. 9 is a schematic cross-sectional view of yet another embodiment of a donor film and a display substrate at one illustrative stage of manufacturing the display device. Elements that are the same as or in correspondence with those described above with reference to FIG. 5 are designated by the same reference numerals, and thus, duplicative descriptions will be omitted to avoid redundancy.

Referring to FIG. 9, the donor film DF may further include a light-to-heat conversion layer CL between the base layer BL and the transfer layer TL. The light-to-heat conversion layer CL may be uniformly formed on the base layer BL overall. The light-to-heat conversion layer CL may absorb the laser beam LB and may convert the absorbed laser beam LB into thermal energy. The thermal energy may be supplied to the transfer layer TL to help deposit an organic material of the transfer layer TL on the display substrate DP effectively.

In an embodiment, the light-to-heat conversion layer CL may include a light-absorbing material. For example, the light-to-heat conversion layer CL may include at least one of molybdenum (Mo), titanium (Ti), chromium (Cr), tungsten (W), tin (Sn), oxides thereof, and sulfides thereof. In some embodiments, the light-to-heat conversion layer CL may further include carbon black, a colored dye, etc.

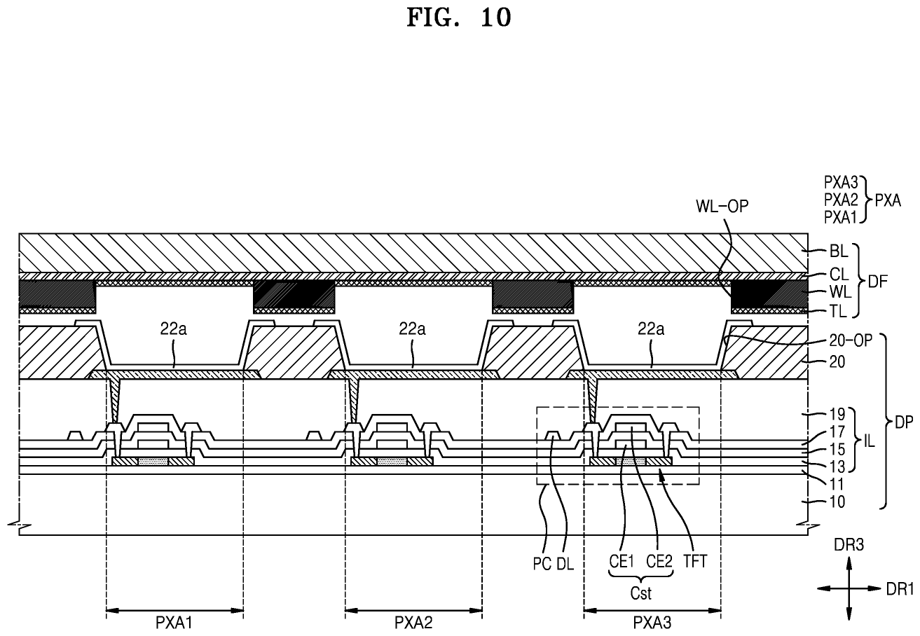

FIG. 10 is a schematic cross-sectional view of still yet another embodiment of a donor film and a display substrate at illustrative stage of manufacturing the display device. Descriptions of equivalent or similar elements as those described with reference to FIG. 9 will be omitted to avoid redundancy.

Referring to FIG. 10, the donor film DF may further include the partition wall layer WL disposed between the light-to-heat conversion layer CL and the transfer layer TL and defining the opening WL-OP overlapping the pixel area PXA of the display substrate DP. That is, the donor film DF may include the base layer BL, the light-to-heat conversion layer CL on the base layer BL, the partition wall layer WL on the light-to-heat conversion layer CL, and the transfer layer TL.

According to the above-described embodiments, an organic material of the transfer layer TL may be transferred onto the display substrate DP by radiating the laser beam LB onto the donor film DF. Thus, an organic material layer such as the emission layer 22b may be formed and/or patterned for each pixel area PXA, and an apparatus for manufacturing a display device does not require the use of a deposition mask such as a fine metal mask (FMM), and is cost-effective and capable of improving manufacturing yield.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. An apparatus for manufacturing a display device, the apparatus comprising:
a support to mount a display substrate having a pixel area;
a multi-layered film disposed above the display substrate and including a light-transmissive base layer and a source layer disposed on the base layer facing the pixel area and comprising an organic material; and
a laser device spaced apart from the multi-layered film to radiate a laser beam toward the multi-layered film,
wherein the source layer is capable of absorbing the laser beam.

2. The apparatus of claim 1, wherein the laser beam has a first wavelength band of about 300 nm to about 700 nm or a second wavelength band of about 800 nm to about 20,000 nm.

3. The apparatus of claim 1, wherein the multi-layered film comprises a donor film, and the source layer comprises a transfer layer having a pattern overlapping the pixel area of the display substrate.

4. The apparatus of claim 1, wherein the laser beam has a first width in one direction and the pixel area has a second width in the same direction, with the first width being substantially equal to or less than the second width.

5. The apparatus of claim 1, wherein the base layer comprises glass or aluminum oxide (Al₂O₃).

6. The apparatus of claim 1, wherein the base layer comprises at least one of silicon (Si), gallium arsenide (GaAs), zinc telluride (ZnTe), and zinc selenide (ZnSe).

7. The apparatus of claim 1, wherein the multi-layered film further comprises a partition wall layer disposed between the base layer and the source layer and defining an opening overlapping the pixel area of the display substrate.

8. The apparatus of claim 7, wherein the partition wall layer has a lower thermal conductivity and a smaller thermal expansion coefficient than that of the source layer.

9. The apparatus of claim 7, wherein the opening of the partition wall layer has a first width in one direction and the pixel area has a second width in the same direction, with the first width being substantially equal to or greater than the second width.

10. The apparatus of claim 7, wherein the partition wall layer is thicker than the source layer.

11. The apparatus of claim 7, wherein the partition wall layer comprises at least one of silicon oxide (SiO₂), silicon nitride (SiNₓ), and aluminum oxide (Al₂O₃).

12. The apparatus of claim 1, wherein the multi-layered film further comprises a light-to-heat conversion layer disposed between the base layer and the source layer and configured to absorb the laser beam.

13. The apparatus of claim 12, wherein the light-to-heat conversion layer comprises at least one of molybdenum (Mo), titanium (Ti), chromium (Cr), tungsten (W), tin (Sn), oxides thereof, and sulfides thereof.

14. The apparatus of claim 12, wherein the multi-layered film further comprises a partition wall layer disposed between the light-to-heat conversion layer and the source layer, the partition wall layer defining an opening overlapping the pixel area of the display substrate.

15. The apparatus of claim 1, further comprising one or more first moveable portions supporting the laser device for movement in one or more directions intersecting an emitting direction of the laser beam.

16. The apparatus of claim 1, further comprising a second moveable portion supporting the display substrate for movement relative to the multi-layered film.

17. The apparatus of claim 1, wherein the laser device comprises a laser beam radiation unit including:
a light source to generate the laser beam; and
an optical system arranged in an emitting path of the laser beam.

18. The apparatus of claim 1, wherein the laser device comprises a vertical-cavity surface-emitting laser (VCSEL).

19. The apparatus of claim 1, wherein the source layer comprises the same material as an emission layer of the display device to emit visible rays.

20. The apparatus of claim 1, wherein the source layer comprises the same material as at least one of a hole injection layer, a hole transport layer, an electron transport layer, and an electron injection layer of the display device.
